(19) United States
(12) Patent Application Publication
(10) Pub. No.: US 2025/0008703 A1
(43) Pub. Date: Jan. 2, 2025

(54) Liquid Cooling System

(71) Applicants: CHINA MOBILE GROUP DESIGN INSTITUTE CO., LTD., Beijing (CN); CHINA MOBILE COMMUNICATIONS GROUP CO., LTD., Beijing (CN)

(72) Inventors: Peng Gao, Beijing (CN); Hongqing Ding, Beijing (CN); Jinfeng Li, Beijing (CN); Hong Liu, Beijing (CN); Xiaojun Lou, Beijing (CN); Meng Gao, Beijing (CN); Yuguang Jiang, Beijing (CN); Lijiang Zhang, Beijing (CN); Guanjun Han, Beijing (CN)

(21) Appl. No.: 18/708,909

(22) PCT Filed: Jan. 30, 2023
(86) PCT No.: PCT/CN2023/073857

§ 371 Date: May 9, 2024

(30) Foreign Application Priority Data
Aug. 25, 2022 (CN) 202211028337.4

(51) Int. Cl. H05K 7/20

(52) U.S. Cl. CPC H05K 7/20836; H05K 7/203; H05K 7/20354; H05K 7/20818

(57) ABSTRACT

A liquid cooling system includes a liquid cooling cabinet, a server immersed in a cooling liquid of the liquid cooling cabinet, a dry cooler, a heat exchanger, a refrigeration device and a controller. The liquid cooling cabinet is connected to the dry cooler to form a natural cold source refrigeration circulation branch. An auxiliary refrigeration circulation branch includes a first circulation branch formed by connecting the liquid cooling cabinet to a hot side of the heat exchanger and a second circulation branch formed by connecting a cold side of the heat exchanger to the refrigeration device. The heat exchanger is connected in parallel with the dry cooler. The controller is configured to control opening or closing of the communication of refrigeration circulation branches including the natural cold source refrigeration circulation branch and the auxiliary refrigeration circulation branch to enter different refrigeration modes.

### CROSS-REFERENCE TO RELATED APPLICATIONS

The present application is a national phase entry under 35 USC § 371 of International Application PCT/CN2023/073857, filed on Jan. 30, 2023, which claims the benefit of and priority to Chinese patent application No. 202211028337.4, titled “liquid cooling system” and filed with China National Intellectual Property Administration on Aug. 25, 2022, the entire contents of which are incorporated herein by reference.

### FIELD

The present application relates to the field of heat exchange of servers, and in particular to a liquid cooling system.

### BACKGROUND

With the rapid development of cloud computing, the data density is getting higher, and requirements for heat dissipation and energy saving of servers for data operation management are getting higher. Therefore, liquid cooling technology stands out from many new server cooling technologies because of its low power usage efficiency (PUE), and the lower the PUE value, the more energy-saving the liquid cooling technology is.

### SUMMARY

Embodiments of the present application provide a liquid cooling system, which includes a liquid cooling cabinet, a server immersed in a cooling liquid of the liquid cooling cabinet, a dry cooler, a heat exchanger, a refrigeration device and a controller; the liquid cooling cabinet is connected to the dry cooler to form a natural cold source refrigeration circulation branch; the liquid cooling cabinet is connected to a hot side of the heat exchanger to form a first circulation branch, a cold side of the heat exchanger is connected to the refrigeration device to form a second circulation branch, an auxiliary refrigeration circulation branch includes the first circulation branch and the second circulation branch, and the heat exchanger is connected in parallel with the dry cooler; and the controller is configured to control opening or closing of the communication of refrigeration circulation branches to enter different refrigeration modes, and the refrigeration circulation branches include the natural cold source refrigeration circulation branch and the auxiliary refrigeration circulation branch.

### BRIEF DESCRIPTION OF THE DRAWINGS

In order to explain the technical scheme of the embodiments of the present application more clearly, the drawings needed to be used in the description of the embodiments of the present application will be briefly introduced below. Obviously, the drawings described below are only some embodiments of the present application. For ordinary skills in the field, other drawings may be obtained according to these drawings without paying creative labor.

FIG. 1 is a schematic structural diagram of a liquid cooling system provided by an embodiment of the present application;

FIG. 2 is a schematic structural diagram of another liquid cooling system provided by an embodiment of the present application;

FIG. 3 is a schematic structural diagram of yet another liquid cooling system provided by an embodiment of the present application;

FIG. 4 is a schematic structural diagram of a liquid cooling system provided by another embodiment of the present application;

FIG. 5 is a schematic structural diagram of another liquid cooling system provided by another embodiment of the present application;

FIG. 6 is a schematic structural diagram of yet another liquid cooling system provided by another embodiment of the present application; and

FIG. 7 is a schematic structural diagram of a liquid cooling system provided by yet another embodiment of the present application.

### DETAILED DESCRIPTION

In order to make those skilled in the technical field better understand the scheme of the present application, the technical scheme in embodiments of the present application will be described clearly and completely in combination with the drawings in embodiments of the present application. Obviously, the described embodiments are only a part of the embodiments of the present application, but not the whole embodiments. Based on the embodiments in the present application, all other embodiments obtained by those of ordinary skill in the field without creative work belong to the protection scope of the present application.

The terms “first” and “second” in the specification and claims of the present application and the above drawings are used to distinguish different objects, not to describe a specific order. Furthermore, that term “comprising/including” and “having” and any variations thereof are intended to cover non-exclusive inclusion. For example, a process, method, system, product or apparatus that includes a series of steps or units is not limited to the listed steps or units, but optionally includes steps or units that are not listed, or optionally includes other steps or units that are inherent to these processes, methods, products or apparatus.

Reference to “an embodiment” herein means that a particular feature, structure or characteristic described in connection with the embodiment may be included in at least one embodiment of the present application. The appearance of this phrase in various places in the specification does not necessarily refer to the same embodiment, nor is it an independent or alternative embodiment mutually exclusive with other embodiments. It is understood explicitly and implicitly by those skilled in the art that the embodiments described herein may be combined with other embodiments.

Generally, when the single-phase immersion liquid cooling technology is applied, the temperature of the cooling liquid in the liquid cooling cabinet increases after absorbing heat, and a corresponding cold source needs to be provided outside the liquid cooling cabinet to dissipate the heat absorbed by the cooling liquid in time, so that the cooled cooling liquid can exchange heat with the server again. In the related art, natural cold sources may be used for refrigeration, but when the temperature of the external environment is high, the temperature of the external environment is not low enough to reduce the temperature of the cooling liquid for cooling, resulting in poor cooling effect. Alternatively, compressors may be used for refrigeration, but the energy consumption of the cooling system in the refrigeration process is large due to the continuous operation of the compressors.

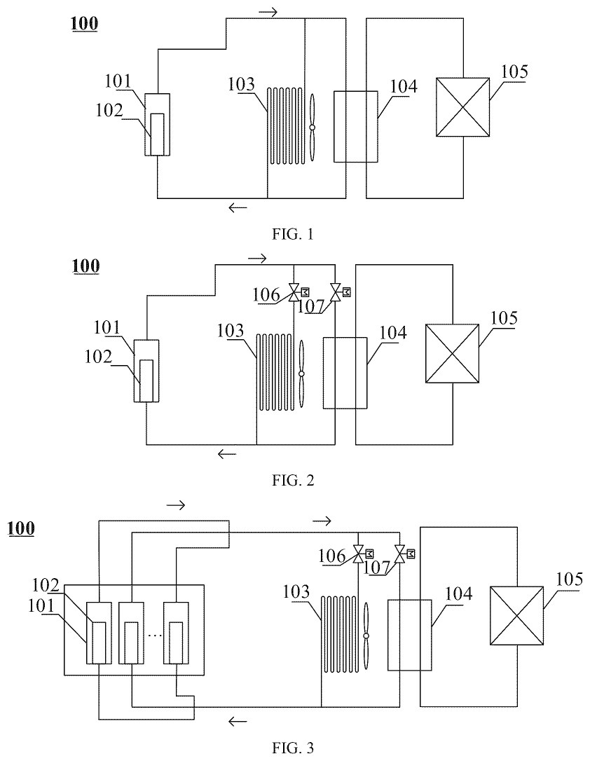

Embodiments of the present application provide a liquid cooling system, referring to FIG. 1, which shows a schematic structural diagram of a liquid cooling system. The liquid cooling system 100 includes a liquid cooling cabinet 101, a server 102 immersed in a cooling liquid of the liquid cooling cabinet, a dry cooler 103, a heat exchanger 104, a refrigeration device 105 and a controller (not shown in the figure).

The liquid cooling cabinet 101 is connected to the dry cooler 103 to form a natural cold source refrigeration circulation branch.

The liquid cooling cabinet 101 is connected to a hot side of the heat exchanger 104 to form a first circulation branch, and a cold side of the heat exchanger 104 is connected to the refrigeration device 105 to form a second circulation branch. An auxiliary refrigeration circulation branch includes the first circulation branch and the second circulation branch, and the heat exchanger 104 is connected in parallel with the dry cooler 103.

The controller is configured to control opening or closing of the communication of the refrigeration circulation branches to enter different refrigeration modes, and the refrigeration circulation branches include the natural cold source refrigeration circulation branch and the auxiliary refrigeration circulation branch.

In embodiments of the present application, the low-temperature cooling liquid may be preferentially introduced into the liquid cooling cabinet 101 where the server 102 is placed, and when the server 102 operates, the low-temperature cooling liquid absorbs the heat generated by the server 102 and the liquid cooling cabinet 101, to obtain the high-temperature cooling liquid. Further, the liquid cooling system 100 cools the high-temperature cooling liquid flowing out of the liquid cooling cabinet 101 by selecting different refrigeration circulation branches, so that the cooled cooling liquid flows back into the liquid cooling cabinet, and then the liquid cooling cabinet 101 and the server 102 are continuously cooled by the circulating cooling liquid.

Here, the controller is electrically connected to the dry cooler 103, the heat exchanger 104 and the refrigeration device 105 separately. The controller takes signal or data acquisition, calculation and processing, analysis and judgment, and countermeasures determination as inputs, sends out control instructions, and then switches the operational states of components in the liquid cooling system based on the control instructions. For example, the controller can control a first regulating valve to open the communication of the natural cold source refrigeration circulation branch, and the controller can also control the first regulating valve to close the communication of the natural cold source refrigeration circulation branch and control a second regulating valve to open the communication of the auxiliary refrigeration circulation branch.

Here, the dry cooler 103 is also called dry type cooler. The operation process of the dry cooler 103 is that the cooling liquid flows in the conduit of the dry cooler, and the cooling liquid in the conduit is cooled by natural wind outside the conduit, to lower the temperature of the cooling liquid in the conduit and achieve the purpose of cooling the cooling liquid.

In embodiments of the present application, the liquid cooling cabinet 101 is in communication with the dry cooler 103 to form the natural cold source refrigeration circulation branch. It may be understood that after the temperature of the cooling liquid in the liquid cooling cabinet 101 rises, the cooling liquid enters the dry cooler 103 along a liquid outlet pipeline from the liquid cooling cabinet 101, and the dry cooler 103 cools the cooling liquid in the conduit through natural wind outside the conduit to achieve the purpose of cooling the cooling liquid. Further, the cooled cooling liquid flows back to the liquid cooling cabinet 101 from the dry cooler 103 through a liquid inlet pipeline to continue cooling the heat generated by the server 102 and the liquid cooling cabinet 101.

Here, the heat exchanger 104 is also called a thermal exchanger. The heat exchanger 104 is a device that transfers part of the heat of a hot fluid to a cold fluid, including but not limited to a plate heat exchanger and a fixed tube-plate heat exchanger. Here, the heat exchanger 104 and the dry cooler 103 are connected in parallel.

Here, the refrigeration device 105 is configured to generate cold air. The refrigeration device 105 may be various refrigeration systems, such as chilled water refrigeration system, air-cooled refrigeration system, etc.

In embodiments of the present application, the liquid cooling cabinet 101 is connected to the hot side of the heat exchanger 104 to form the first circulation branch, and the cold side of the heat exchanger 104 is connected to the refrigeration device 105 to form the second circulation branch. The auxiliary refrigeration circulation branch may be understood as follows: after the temperature of the cooling liquid in the liquid cooling cabinet 101 rises, the cooling liquid enters the hot side of the heat exchanger 104 from the liquid cooling cabinet 101 along the liquid outlet pipeline, and at the same time, the refrigeration device is started to generate cold air which flows to the cold side of the heat exchanger 104 through a cooling conduit. At this time, the liquid cooling system exchanges heat between high-temperature cooling liquid and cold air through the heat exchanger 104, and then cools the cooling liquid to achieve the purpose of cooling the cooling liquid. Further, the cooled cooling liquid flows back to the liquid cooling cabinet 101 from the hot side of the heat exchanger 104 through the liquid inlet pipeline to continue the continuous cooling treatment of the server 102 and the liquid cooling cabinet 101.

It may be seen that the liquid cooling system provided by the embodiments of the present application only reuses the parts of the liquid cooling cabinet and the server for the natural cold source refrigeration circulation branch and the auxiliary refrigeration circulation branch, and selects to open or close the communication of different refrigeration circulation branches to enter different refrigeration modes to cool the cooling liquid, and then uses the cooled cooling liquid to continuously absorb the heat generated by the liquid cooling cabinet and the server. In this way, it not only solves the problem of poor cooling effect when only natural cold source is used for refrigeration, but also avoids the continuous operation of the compressor, thus saving power resources and energy, ensuring the reliability of the system, and maintaining the reliable operation of the server.

In some embodiments, referring to FIG. 2, the liquid cooling system 100 further includes a first regulating valve 106 and a first temperature sensor (not shown in the figure) arranged at the liquid outlet of the liquid cooling cabinet 101, and the first regulating valve 106 is arranged in the natural cold source refrigeration circulation branch. The first temperature sensor is configured to detect a liquid outlet temperature of the cooling liquid flowing out of the liquid cooling cabinet 101.

The controller is also configured to obtain a first instruction to enter a natural refrigeration mode, and in response to the first instruction, control the first regulating valve 106 to open the communication of the natural cold source refrigeration circulation branch and control the dry cooler 103 to operate.

The controller is further configured to obtain an ambient temperature and obtain a first difference of the liquid outlet temperature minus the ambient temperature, and generate the first instruction when the first difference is greater than or equal to a first temperature threshold.

Here, the first temperature threshold may be any value within a preset range such as 8° C.-12° C., e.g., 10° C.

In embodiments of the present application, the controller is electrically connected to the first regulating valve 106 and the first temperature sensor separately. The controller is configured to control opening and closing of the first regulating valve 106, thereby controlling opening and closing of the communication of the natural cold source refrigeration circulation branch, and obtain the liquid outlet temperature of the cooling liquid collected by the first temperature sensor. Here, the first regulating valve 106 is connected to the dry cooler 103, that is, the first regulating valve 106 is arranged between the liquid cooling cabinet 101 and the dry cooler 103. Here, the first regulating valve 106 may be an electric regulating valve.

In embodiments of the present application, the controller is further configured to obtain the ambient temperature of a space where the liquid cooling cabinet is located, calculate a first difference of the liquid outlet temperature minus the ambient temperature, and generate a first instruction to enter the natural refrigeration mode when the first difference is greater than or equal to the first temperature threshold. Further, the controller is also configured to, in response to the first instruction, control the first regulating valve 106 to open, and control the dry cooler 103 to operate, to control the communication of the refrigeration circulation branch of the natural cold source to open, thereby entering the natural refrigeration mode. Then, the cooling liquid in the conduit of the dry cooler 103 is cooled by the natural wind outside the conduit through the dry cooler 103, thus achieving the purpose of cooling the cooling liquid.

In some embodiments, continuing to refer to FIG. 2, the liquid cooling system 100 further includes a second regulating valve 107 and a first temperature sensor (not shown in the figure) arranged at the liquid outlet of the liquid cooling cabinet 101. The second regulating valve 107 is arranged in the first circulation branch, and the first temperature sensor is configured to detect the liquid outlet temperature of the cooling liquid flowing out of the liquid cooling cabinet 101.

The controller is further configured to obtain a second instruction to enter an auxiliary refrigeration mode, and in response to the second instruction, control the second regulating valve 107 to open the communication of the auxiliary refrigeration circulation branch and control the refrigeration device 105 to operate.

The controller is further configured to obtain the ambient temperature and obtain the first difference of the liquid outlet temperature minus the ambient temperature, and generate the second instruction when the first difference is less than the first temperature threshold.

Here, the first temperature threshold may be any value within a preset range such as 8° C.-12° C., e.g., 10° C.

In embodiments of the present application, the controller is electrically connected to the second regulating valve 107 and the first temperature sensor separately. The controller is configured to control opening and closing of the second regulating valve 107, thereby controlling opening and closing of the communication of the auxiliary refrigeration circulation branch, and obtain the liquid outlet temperature of the cooling liquid collected by the first temperature sensor. It should be noted that the second regulating valve 107 is connected to the hot side of the heat exchanger 104, and a branch formed by connecting the second regulating valve 107 with the hot side of the heat exchanger 104 is connected in parallel with a branch formed by connecting the first regulating valve 106 with the dry cooler 103, and then connected in series with the liquid cooling cabinet 101. Here, the second regulating valve 107 may be an electric regulating valve.

In embodiments of the present application, the controller is further configured to obtain the ambient temperature of the space where the liquid cooling cabinet is located, calculate the first difference of the liquid temperature minus the ambient temperature, and generate the second instruction to enter the auxiliary refrigeration mode when the first difference is less than the first temperature threshold. Further, the controller is also configured to, in response to the second instruction, control the second regulating valve 107 to open, and control the refrigeration device 105 to operate to generate cold air, to control the communication of the auxiliary refrigeration circulation branch to open, thereby entering the auxiliary refrigeration mode. Further, a pipeline where the high-temperature cooling liquid of the first circulation branch is located and a pipeline where the cold air of the second circulation branch is located exchange heat indirectly through the heat exchanger 104, thus achieving the purpose of cooling the cooling liquid.

In some embodiments, continuing to refer to FIG. 2, the controller is further configured to obtain a third instruction to switch from the natural refrigeration mode to the auxiliary refrigeration mode, and in response to the third instruction, control the first regulating valve 106 to close the communication of the natural cold source refrigeration circulation branch, control the dry cooler 103 to stop operation, control the second regulating valve 107 to open the communication of the first circulation branch, and control the refrigeration device 105 to operate.

The controller is further configured to obtain the ambient temperature, obtain the first difference of the liquid outlet temperature minus the ambient temperature, obtain a first duration of the first difference greater than or equal to the first temperature threshold when the first difference is greater than or equal to the first temperature threshold, and generate the third instruction when the first duration is greater than or equal to a first duration threshold.

In embodiments of the present application, the first duration threshold may be any value within a preset range such as 25-35 minutes (min), e.g., 30 minutes.

In embodiments of the present application, a branch formed by connecting the second regulating valve 107 with the hot side of the heat exchanger 104 is connected in parallel with a branch formed by connecting the first regulating valve 106 with the dry cooler 103, and then connected in series with the liquid cooling cabinet 101.

In embodiments of the present application, the controller is further configured to obtain the ambient temperature of the space where the liquid cooling cabinet is located, calculate the first difference of the liquid temperature minus the ambient temperature, obtain the first duration of the first difference greater than or equal to the first temperature threshold when the first difference is greater than or equal to the first temperature threshold, and generate the third instruction to switch from the natural refrigeration mode to the auxiliary refrigeration mode when the first duration is greater than or equal to the first duration threshold. In this way, by setting the first duration threshold, frequent switching between different refrigeration modes is avoided, and frequent restart and stop of the dry cooler and refrigeration device are also avoided, thus slowing down the loss of apparatus and saving power resources. Further, the controller is also configured to, in response to the third instruction, control the first regulating valve 106 to close the communication of the natural cold source refrigeration circulation branch, control the dry cooler 103 to stop operation, control the second regulating valve 107 to open the communication of the first circulation branch, and control the refrigeration device 105 to operate, so that the refrigeration device 105 generates cold air, thus controlling the communication of the auxiliary refrigeration circulation branch to open, and achieving the purpose of switching from the natural refrigeration mode to the auxiliary refrigeration mode. Further, the pipeline where the high-temperature cooling liquid of the first circulation branch is located and the pipeline where the cold air of the second circulation branch is located exchange heat indirectly through the heat exchanger 104, thus achieving the purpose of cooling the cooling liquid.

In some embodiments, continuing to refer to FIG. 2, the controller is further configured to obtain a fourth instruction to switch from the auxiliary refrigeration mode to the natural refrigeration mode, and in response to the fourth instruction, control the first regulating valve 106 to open the communication of the natural cold source refrigeration circulation branch, control the dry cooler 103 to operate, control the second regulating valve 107 to close the communication of the first circulation branch, and control the refrigeration device 105 to stop operation.

The controller is further configured to obtain the ambient temperature, obtain the first difference of the liquid outlet temperature minus the ambient temperature, obtain the first duration of the first difference is less than the first temperature threshold when the first difference is less than the first temperature threshold, and generate the fourth instruction when the first duration is greater than or equal to the first duration threshold.

In embodiments of the present application, the first duration threshold may be any value within a preset range, such as 25-35 minutes (min), e.g., 30 minutes.

In embodiments of the present application, the branch formed by connecting the second regulating valve 107 with the hot side of the heat exchanger 104 is connected in parallel with the branch formed by connecting the first regulating valve 106 with the dry cooler 103, and then connected in series with the liquid cooling cabinet 101.

In embodiments of the present application, the controller is further configured to obtain the ambient temperature of the space where the liquid cooling cabinet is located, calculate the first difference of the liquid temperature minus the ambient temperature, obtain the first duration of the first difference less than the first temperature threshold when the first difference is less than the first temperature threshold, and generate the fourth instruction to switch from the auxiliary refrigeration mode to the natural refrigeration mode when the first duration is greater than or equal to the first duration threshold. In this way, by setting the first duration threshold, frequent switching between different refrigeration modes is avoided, and frequent restart and stop of the dry cooler and refrigeration device are also avoided, thus slowing down the loss of apparatus and saving power resources. Further, the controller is also configured to, in response to the fourth instruction, control the first regulating valve 106 to open the communication of the natural cold source refrigeration circulation branch, control the dry cooler 103 to operate, control the second regulating valve 107 to close the communication of the first circulation branch, and control the refrigeration device 105 to stop operation, to control the communication of the natural cold source refrigeration circulation branch to open, thus realizing the purpose of switching from the auxiliary refrigeration mode to the natural refrigeration mode. Further, the cooling liquid in the conduit of the dry cooler 103 is cooled by the natural wind outside the conduit through the dry cooler 103, thus achieving the purpose of cooling the cooling liquid.

In other embodiments of the present application, the controller is also configured to obtain a fifth instruction to start a dual refrigeration mode, and in response to the fifth instruction, control the first regulating valve 106 to open the communication of the natural cold source refrigeration circulation branch, control the dry cooler 103 to operate, control the second regulating valve 107 to open the communication of the first circulation branch, and control the refrigeration device 105 to operate.

The controller is further configured to obtain the ambient temperature, obtain the first difference of the liquid outlet temperature minus the ambient temperature, obtain the first duration of the first difference less than a fourth temperature threshold when the first difference is less than the fourth temperature threshold, and generate the fifth instruction when the first duration is greater than or equal to the first duration threshold. The fourth temperature threshold is smaller than the first temperature threshold.

Here, the fourth temperature threshold is a threshold configured to start the dual refrigeration mode.

In embodiments of the present application, the controller is further configured to obtain the ambient temperature of the space where the liquid cooling cabinet is located, calculate the first difference of the liquid temperature minus the ambient temperature, obtain the first duration of first difference less than the fourth temperature threshold when the first difference is less than the fourth temperature threshold, and generate the fifth instruction to start the dual refrigeration mode when the first duration is greater than or equal to the first duration threshold. Further, in response to the fifth instruction, the controller is also configured to control the first regulating valve 106 to open the communication of the natural cold source refrigeration circulation branch, control the dry cooler 103 to operate, control the second regulating valve 107 to open the communication of the first circulation branch, and control the refrigeration device 105 to operate, to control the communication of the natural cold source refrigeration circulation branch and the communication of the compressor refrigeration circulation branch to open, thus realizing the purpose of rapidly cooling the cooling liquid by starting the dual refrigeration mode.

In some embodiments, referring to FIG. 3, the liquid cooling system 100 further includes a plurality of liquid cooling cabinets 101 and a first temperature sensor (not shown in the figure) arranged at the liquid outlet of each liquid cooling cabinet 101, and each first temperature sensor is configured to detect a sub-liquid outlet temperature of the cooling liquid flowing out of each liquid cooling cabinet.

The controller is further configured to determine an average value of all sub-liquid outlet temperatures as the liquid outlet temperature.

In embodiments of the present application, the controller is electrically connected to each first temperature sensor, to obtain the sub-liquid outlet temperature of the cooling liquid in a corresponding liquid cooling cabinet 101 collected by each first temperature sensor.

In embodiments of the present application, each liquid cooling cabinet 101 is provided with a liquid outlet and a liquid outlet branch in communication with the liquid outlet. A plurality of liquid outlet branches is in communication with the liquid outlet pipeline. After the temperature of the cooling liquid in each liquid cooling cabinet rises, the cooling liquid flows out from the liquid outlet of each liquid cooling cabinet and flows to the liquid outlet pipeline along a corresponding liquid outlet branch. At this time, the cooling liquid enters the dry cooler 103 or the hot side of the heat exchanger 104 through the liquid outlet pipeline, to cool the heated cooling liquid to achieve the purpose of cooling. At the same time, the controller averages all the obtained sub-liquid outlet temperatures to determine the liquid outlet temperature, so that the balance of the liquid outlet temperature of the cooling liquid among the plurality of liquid cooling cabinets is taken into account, and the switching of different refrigeration modes is realized according to the relationship between the balanced liquid outlet temperature and the ambient temperature.

In some embodiments, referring to FIGS. 1 to 3, the liquid cooling system 100 further includes a second temperature sensor (not shown in the figure) arranged at a liquid inlet of the liquid cooling cabinet 101, and the second temperature sensor is configured to detect a liquid inlet temperature of the cooling liquid flowing into the liquid cooling cabinet 101.

The controller is further configured to obtain a parameter raising instruction for controlling a fan frequency of the dry cooler 103 or a refrigeration capacity of the refrigeration device 105, and in response to the parameter raising instruction, raise the fan frequency of the dry cooler 103 or increase the refrigeration capacity of the refrigeration device 105.

The controller is further configured to obtain a second duration of the liquid inlet temperature greater than a second temperature threshold when the liquid inlet temperature is greater than the second temperature threshold, and generate the parameter raising instruction when the second duration is greater than or equal to a second duration threshold.

In embodiments of the present application, the second temperature threshold may be any value within a preset range such as 42-47° C., e.g., 45° C.

In embodiments of the present application, the second duration threshold may be any value within a preset range such as 13-18 min, e.g., 15 min.

In embodiments of the present application, the liquid cooling cabinet 101 is provided with a liquid inlet and a liquid inlet pipeline in communication with the liquid inlet, and the other end of the liquid inlet pipeline is connected to a cooling liquid output end of the dry cooler 103 or a cooling liquid output end of the hot side of the heat exchanger 104.

In embodiments of the present application, since the fan of the dry cooler 103 and the refrigeration device 105 are both variable frequency apparatus, the fan frequency of the dry cooler 103 or the refrigeration capacity of the refrigeration device 105 may be adjusted according to the input control instruction.

Here, when the liquid cooling system is in the natural refrigeration mode, after the temperature of the cooling liquid in the liquid cooling cabinet 101 rises, the cooling liquid enters the dry cooler 103 from the liquid cooling cabinet 101 along the liquid outlet pipeline, and the cooling liquid in the conduit of the dry cooler 103 is cooled by the natural wind outside the conduit through the dry cooler 103, and the cooled cooling liquid flows back to the liquid cooling cabinet 101 along the liquid inlet pipeline. Further, the liquid cooling system 100 collects the liquid inlet temperature of the cooling liquid flowing back to the liquid cooling cabinet 101 through the second temperature sensor. When the liquid inlet temperature is greater than the second temperature threshold, it indicates that the current temperature of the cooling liquid is still high, and it is necessary to strengthen the heat exchange with the outside. At this time, the second duration of the liquid inlet temperature greater than the second temperature threshold is obtained. When the second duration is greater than or equal to the second duration threshold, the parameter raising instruction for controlling the fan frequency of the dry cooler 103 is generated. In this way, by setting the second duration threshold, frequent switching of the fan rotating speed of the dry cooler is avoided, thereby slowing down the loss of apparatus and saving power resources. Further, the controller also, in response to the parameter raising instruction, raises the fan frequency or rotating speed of the dry cooler, and speeds up the heat exchange process of the dry cooler to the cooling liquid, thus rapidly cooling the cooling liquid, continuing to cool the liquid cooling cabinet and the server through the cooled cooling liquid, and maintaining the reliable operation of the server.

Here, when the liquid cooling system is in the auxiliary refrigeration mode, after the temperature of the cooling liquid in the liquid cooling cabinet 101 rises, the cooling liquid enters the hot side of the heat exchanger 104 from the liquid cooling cabinet 101 along the liquid outlet pipeline, and indirect heat exchange between the high-temperature cooling liquid in the first circulation branch and the cold air in the second circulation branch is performed through the heat exchanger 104, thereby cooling the cooling liquid. Then, the cooled cooling liquid flows back to the liquid cooling cabinet 101 along the liquid inlet pipeline. Further, the liquid cooling system 100 collects the liquid inlet temperature of the cooling liquid flowing back to the liquid cooling cabinet 101 through the second temperature sensor. When the liquid inlet temperature is greater than the second temperature threshold, it indicates that the current temperature of the cooling liquid is still high, and it is necessary to strengthen the heat exchange with the outside. At this time, the second duration of the liquid inlet temperature greater than the second temperature threshold is obtained. When the second duration is greater than or equal to the second duration threshold, the parameter raising instruction for controlling the refrigerating capacity of the refrigerating device 105 is generated. In this way, by setting the second duration threshold, the frequent switching of refrigeration capacity of the refrigeration device is avoided, thereby slowing down the loss of apparatus and saving power resources. Further, the controller also, in response to the parameter raising instruction, increases the refrigerating capacity of the refrigeration device, and speeds up the heat exchange process between the cooling liquid and the cold air, thus rapidly cooling the cooling liquid, continuing to cool the liquid cooling cabinet and the server through the cooled cooling liquid, and maintaining the reliable operation of the server.

In some embodiments, referring to FIGS. 1 to 3, the liquid cooling system 100 further includes a second temperature sensor (not shown in the figure) arranged at the liquid inlet of the liquid cooling cabinet, and the second temperature sensor is configured to detect the liquid inlet temperature of the cooling liquid flowing into the liquid cooling cabinet.

The controller is further configured to obtain a parameter reduction instruction for controlling the fan frequency of the dry cooler 103 or the refrigeration capacity of the refrigeration device 105, and in response to the parameter reduction instruction, reduce the fan frequency of the dry cooler 103 or the refrigeration capacity of the refrigeration device 105.

The controller is further configured to obtain the second duration of the liquid inlet temperature less than or equal to the second temperature threshold when the liquid inlet temperature is less than or equal to the second temperature threshold, and generate the parameter reduction instruction when the second duration is greater than or equal to the second duration threshold.

In embodiments of the present application, the second temperature threshold may be any value within a preset range such as 42-47° C., e.g., 45° C.

In embodiments of the present application, the second duration threshold may be any value within a preset range such as 13-18 min, e.g., 15 min.

In embodiments of the present application, the liquid cooling cabinet 101 is provided with a liquid inlet and a liquid inlet pipeline in communication with the liquid inlet, and the other end of the liquid inlet pipeline is connected to the cooling liquid output end of the dry cooler 103 or the cooling liquid output end of the hot side of the heat exchanger 104.

In embodiments of the present application, since the fan of the dry cooler 103 and the refrigeration device 105 are both variable frequency apparatus, the fan frequency of the dry cooler 103 or the refrigeration capacity of the refrigeration device 105 may be adjusted according to the input control instruction.

Here, when the liquid cooling system is in the natural refrigeration mode, after the temperature of the cooling liquid in the liquid cooling cabinet 101 rises, the cooling liquid enters the dry cooler 103 from the liquid cooling cabinet 101 along the liquid outlet pipeline, and the cooling liquid in the conduit of the dry cooler 103 is cooled by the natural wind outside the conduit through the dry cooler 103, and the cooled cooling liquid flows back to the liquid cooling cabinet 101 along the liquid inlet pipeline. Further, the liquid cooling system 100 collects the liquid inlet temperature of the cooling liquid flowing back to the liquid cooling cabinet 101 through the second temperature sensor. When the liquid inlet temperature is less than or equal to the second temperature threshold, it indicates that the current temperature of the cooling liquid is low, and there is no need for excessive heat exchange with the outside. At this time, a second duration of the liquid inlet temperature less than or equal to the second temperature threshold is obtained; When the second duration is greater than or equal to the second duration threshold, the parameter reduction instruction for controlling the fan frequency of the dry cooler 103 is generated. In this way, by setting the second duration threshold, frequent switching of the fan rotating speed of the dry cooler is avoided, thereby slowing down the loss of apparatus and saving power resources. Further, the controller also, in response to the parameter reduction instruction, reduces the fan frequency or rotating speed of the dry cooler, and slows down the heat exchange process of the dry cooler to the cooling liquid, thus realizing the cooling of the cooling liquid, continuing to cool the liquid cooling cabinet and the server through the cooled cooling liquid, and maintaining the reliable operation of the server.

Here, when the liquid cooling system is in the auxiliary refrigeration mode, after the temperature of the cooling liquid in the liquid cooling cabinet 101 rises, the cooling liquid enters the hot side of the heat exchanger 104 from the liquid cooling cabinet 101 along the liquid outlet pipeline, and indirect heat exchange between the high-temperature cooling liquid in the first circulation branch and the cold air in the second circulation branch is performed through the heat exchanger 104, thereby cooling the cooling liquid. Then, the cooled cooling liquid flows back to the liquid cooling cabinet 101 along the liquid inlet pipeline. Further, the liquid cooling system 100 collects the liquid inlet temperature of the cooling liquid flowing back to the liquid cooling cabinet 101 through the second temperature sensor. When the liquid inlet temperature is less than or equal to the second temperature threshold, it indicates that the current temperature of the cooling liquid is low, and there is no need for excessive heat exchange with the outside. At this time, a second duration of the liquid inlet temperature less than or equal to the second temperature threshold is obtained. When the second duration is greater than or equal to the second duration threshold, the parameter reduction instruction configured to control the refrigerating capacity of the refrigerating device 105 is generated. In this way, by setting the second duration threshold, the frequent switching of refrigeration capacity of the refrigeration device is avoided, thereby slowing down the loss of apparatus and saving power resources. Further, the controller also, in response to the parameter reduction instruction, reduces the refrigerating capacity of the refrigeration device, and slows down the heat exchange process between the cooling liquid and the cold air, thus realizing the cooling of the cooling liquid, continuing to cool the liquid cooling cabinet and the server through the cooled cooling liquid, and maintaining the reliable operation of the server.

In some embodiments, continuing to refer to FIG. 3, the liquid cooling system 100 further includes a plurality of liquid cooling cabinets 101 and a second temperature sensor (not shown in the figure) arranged at the liquid inlet of each liquid cooling cabinet 101, and each second temperature sensor is configured to detect a sub-liquid inlet temperature of the cooling liquid flowing into each liquid cooling cabinet 101.

The controller is further configured to determine an average value of all sub-liquid inlet temperatures as the liquid inlet temperature.

In embodiments of the present application, the controller is electrically connected to each second temperature sensor, to obtain the sub-liquid inlet temperature of the cooling liquid in a corresponding liquid cooling cabinet 101 collected by each second temperature sensor.

In embodiments of the present application, each liquid cooling cabinet 101 is provided with a liquid inlet and a liquid inlet branch in communication with the liquid inlet. A plurality of liquid inlet branches is in communication with the liquid inlet pipeline. After cooling, the cooling liquid flows to each liquid inlet branch along the liquid inlet pipeline, and then to the liquid cooling cabinet 101 corresponding to the liquid inlet branch, and continues to cool the liquid cooling cabinet 101 and the server 102. At the same time, the controller averages all the obtained sub-liquid inlet temperatures to determine the liquid inlet temperature. In this way, the balance of liquid inlet temperature of the cooling liquid among the plurality of liquid cooling cabinets is taken into account, so that the fan frequency of the dry cooler or the refrigeration capacity of the refrigeration device may be controlled and adjusted according to the relationship between the balanced liquid inlet temperature and the temperature threshold.

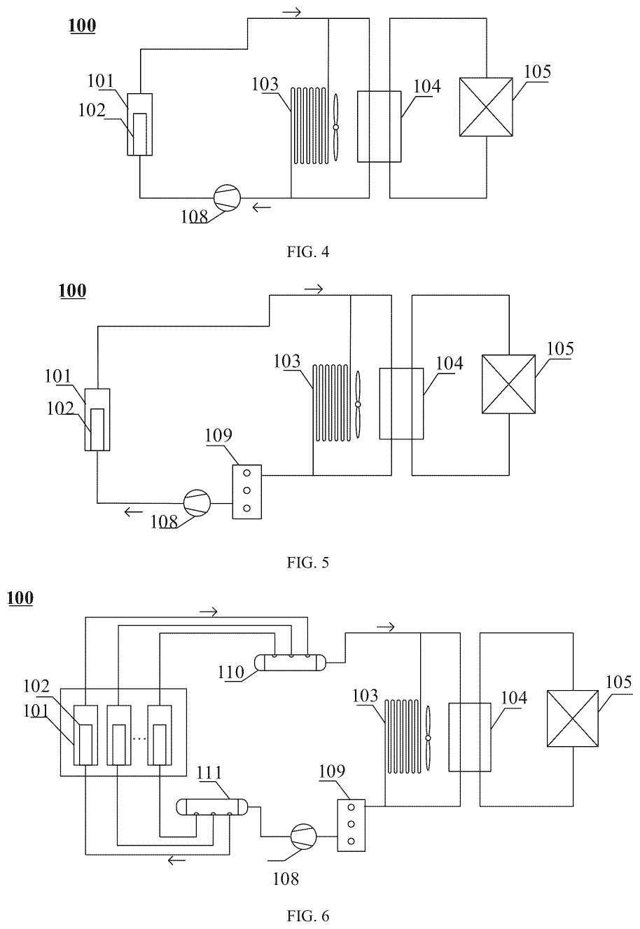

In some embodiments, referring to FIG. 4, the liquid cooling system 100 further includes a liquid pump 108 and a third temperature sensor (not shown in the figure) arranged on the server 102. The liquid pump 108 is arranged between the liquid cooling cabinet 101 and the dry cooler 103 or between the liquid cooling cabinet 101 and the hot side of the heat exchanger 104. The third temperature sensor is configured to detect a surface temperature of the server.

The controller is further configured to obtain a frequency raising instruction for controlling a liquid pump frequency of the liquid pump 108, and raise the liquid pump frequency of the liquid pump 108 in response to the frequency raising instruction.

The controller is further configured to obtain a third duration of the surface temperature greater than a third temperature threshold when the surface temperature is greater than the third temperature threshold, and generate the frequency raising instruction when the third duration is greater than or equal to a third duration threshold.

In embodiments of the present application, the third temperature threshold may be any value within a preset range such as 65-75° C., e.g., 70° C.

In embodiments of the present application, the third duration threshold may be any value within a preset range such as 8-12 min, e.g., 10 min.

In embodiments of the present application, the liquid pump 108 provides power for the whole circulation. It should be noted that since the liquid pump 108 is a variable frequency apparatus, the frequency of the liquid pump 108 may be adjusted according to the input control instruction.

In embodiments of the present application, the controller is electrically connected to the liquid pump 108 and the third temperature sensor separately, to adjust the frequency of the liquid pump 108 according to the temperature of the server 102 collected by the third temperature sensor.

In embodiments of the present application, the liquid pump 108 may be arranged between the liquid outlet of the liquid cooling cabinet 101 and a liquid inlet end of the dry cooler 103, or the liquid pump 108 may be arranged between the liquid outlet of the liquid cooling cabinet 101 and a liquid inlet end of the heat exchanger 104. The liquid pump 108 may also be arranged between the liquid inlet of the liquid cooling cabinet 101 and a liquid outlet end of the dry cooler 103, or the liquid pump 108 may be arranged between the liquid inlet of the liquid cooling cabinet 101 and a liquid outlet end of the heat exchanger 104. In order to avoid the influence of high-temperature cooling liquid on the liquid pump and prolong a service life of the liquid pump, the liquid pump 108 is arranged between the liquid inlet of the liquid cooling cabinet 101 and the liquid outlet end of the dry cooler 103, or the liquid pump 108 may be arranged between the liquid inlet of the liquid cooling cabinet 101 and the liquid outlet end of the heat exchanger 104.

In embodiments of the present application, whether the liquid cooling system is in the natural refrigeration mode or the auxiliary refrigeration mode, if the surface temperature of the server detected by the third temperature sensor is greater than the third temperature threshold, it indicates that the current surface temperature of the server is relatively high, and it is necessary to speed up the circulation speed of the cooling liquid and improve the cooling capacity to rapidly cool the server. At this time, the controller also obtains a third duration of the surface temperature greater than a third temperature threshold, and generates a frequency raising instruction for controlling the liquid pump frequency of the liquid pump. In this way, by setting the third duration threshold, frequent switching of the rotating speed of the liquid pump is avoided, thereby slowing down the loss of apparatus and saving power resources. Further, the controller also, in response to the frequency raising instruction, increases the frequency or rotating speed of the liquid pump, speeds up the circulation speed of the cooling liquid, and improves the refrigeration capacity, thus rapidly cooling the server.

In some embodiments, continuing to refer to FIG. 4, the liquid cooling system 100 further includes a liquid pump 108 and a third temperature sensor (not shown in the figure) arranged on the server 102. The liquid pump 108 is arranged between the liquid cooling cabinet 101 and the dry cooler 103 or between the liquid cooling cabinet 101 and the hot side of the heat exchanger 104. The third temperature sensor is configured to detect the surface temperature of the server.

The controller is further configured to obtain a frequency reduction instruction for controlling the liquid pump frequency of the liquid pump, and reduce the liquid pump frequency of the liquid pump in response to the frequency reduction instruction.

The controller is further configured to obtain a third duration of the surface temperature less than or equal to the third temperature threshold when the surface temperature is less than or equal to the third temperature threshold, and generate the frequency reduction instruction when the third duration is greater than or equal to the third duration threshold.

In embodiments of the present application, the third temperature threshold may be any value within a preset range such as 65-75° C., e.g., 70° C.

In embodiments of the present application, the third duration threshold may be any value within a preset range such as 8-12 min, e.g., 10 min.

In embodiments of the present application, the controller is electrically connected to the liquid pump 108 and the third temperature sensor separately, to adjust the frequency of the liquid pump 108 according to the temperature of the server collected by the third temperature sensor.

In embodiments of the present application, whether the liquid cooling system is in the natural refrigeration mode or the auxiliary refrigeration mode, if the surface temperature of the server detected by the third temperature sensor is less than or equal to the third temperature threshold, it indicates that the current surface temperature of the server is low, the circulation speed of the cooling liquid may be slowed down and the refrigeration capacity of the liquid cooling system may be reduced, thereby realizing the cooling of the server. At this time, the controller also obtains the third duration of the surface temperature less than or equal to the third temperature threshold, and generates the frequency reduction instruction for controlling the frequency of the liquid pump. In this way, by setting the third duration threshold, frequent switching of the rotating speed of the liquid pump is avoided, thereby slowing down the loss of apparatus and saving power resources. Further, the controller also, in response to the frequency reduction instruction, reduces the frequency or rotating speed of the liquid pump, slows down the circulation speed of the cooling liquid, and reduces the refrigeration capacity of the liquid cooling system, thus realizing the cooling of the server.

In other embodiments of the present application, the liquid cooling system 100 further includes a plurality of liquid cooling cabinets 101 and a third temperature sensor (not shown in the figure) arranged on each server 102, and at least one server 102 is immersed in each liquid cooling cabinet 101. Each third temperature sensor is configured to detect a surface temperature of each server. The controller is further configured to filter out the surface temperature with the highest temperature from all surface temperatures. In this way, the highest surface temperature is selected from a plurality of surface temperatures, and the server corresponding to the highest surface temperature is prevented from being burnt out by taking the highest surface temperature as a reference. Further, the frequency of the liquid pump is adjusted according to the relationship between the highest surface temperature and the temperature threshold.

In some embodiments, referring to FIG. 5, the liquid cooling system 100 further includes a liquid storage tank 109, which is arranged between the liquid pump 108 and the dry cooler 103 or between the liquid pump 108 and the hot side of the heat exchanger 104.

In embodiments of the present application, the liquid storage tank 109 may be arranged between a liquid outlet end of the liquid pump 108 and the liquid inlet end of the dry cooler 103, or between the liquid outlet end of the liquid pump 108 and the liquid inlet end of the hot side of the heat exchanger 104. The liquid storage tank 109 may be arranged between a liquid inlet end of the liquid pump 108 and the liquid outlet end of the dry cooler 103, or between the liquid inlet end of the liquid pump 108 and the liquid outlet end of the hot side of the heat exchanger 104. In order to avoid the influence of high-temperature cooling liquid on the liquid storage tank and prolong a service life of the liquid storage tank, the liquid storage tank 109 may be arranged between the liquid inlet end of the liquid pump 108 and the liquid outlet end of the dry cooler 103, or between the liquid inlet end of the liquid pump 108 and the liquid outlet end of the hot side of the heat exchanger 104. In this way, the liquid storage tank can not only prevent the cavitation of the liquid pump, but also play a role in regulating the flow of cooling liquid under different refrigeration modes.

In some embodiments, referring to FIG. 6, the liquid cooling system 100 further includes a liquid collector 110, which is arranged between the liquid outlet of the liquid cooling cabinet 101 and the liquid inlet end of the dry cooler 103, or between the liquid outlet of the liquid cooling cabinet 101 and the liquid inlet end of the hot side of the heat exchanger 104.

In embodiments of the present application, the liquid cooling system further includes a plurality of liquid cooling cabinets 101, and each liquid inlet branch pipe of the liquid collector 110 is connected to the liquid outlet of respective liquid cooling cabinet 101, and a liquid outlet branch pipe of the liquid collector 110 is connected to the liquid inlet end of the dry cooler 103 through the liquid outlet pipeline, or the liquid outlet branch pipe of the liquid collector 110 is connected to the liquid inlet end of the hot side of the heat exchanger 104 through the liquid outlet pipeline. In this way, the liquid cooling system is provided with the liquid collector, which plays a role in buffering, stabilizing flow and mixing.

In some embodiments, continuing to refer to FIG. 6, the liquid cooling system 100 further includes a liquid distributor 111, which is arranged between the liquid inlet of the liquid cooling cabinet 101 and the liquid outlet end of the dry cooler 103, or between the liquid inlet of the liquid cooling cabinet 101 and the liquid outlet end of the hot side of the heat exchanger 104.

In embodiments of the present application, the liquid cooling system further includes a plurality of liquid cooling cabinets 101, and each liquid outlet branch pipe of the liquid distributor 111 is connected to the liquid inlet of respective liquid cooling cabinet 101, and a liquid inlet branch pipe of the liquid distributor 111 is connected to the liquid outlet end of the dry cooler 103 through the liquid inlet pipeline, or the liquid inlet branch pipe of the liquid distributor 111 is connected to the liquid outlet end of the hot side of the heat exchanger 104 through the liquid inlet pipeline.

In other embodiments of the present application, the liquid pump 108 is arranged between the liquid inlet of the liquid cooling cabinet 101 and the liquid outlet end of the dry cooler 103, and the liquid distributor 111 is arranged between the liquid inlet of the liquid cooling cabinet 101 and the liquid outlet end of the liquid pump 108. In this way, the liquid cooling system is provided with the liquid distributor, which plays the role of buffering, stabilizing flow, mixing and evenly distributing fluid, thus ensuring the stability of the flow in the system and the safety of all components of the system.

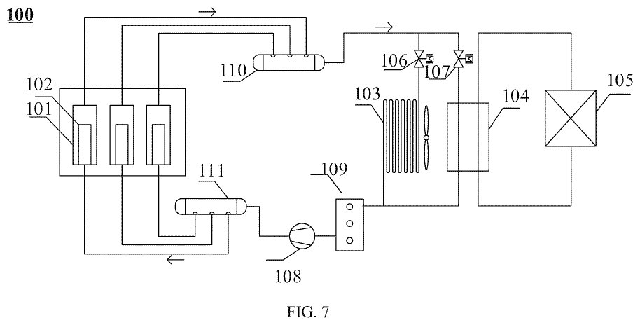

In an achievable scenario, referring to FIG. 7, the liquid cooling system 100 includes a plurality of liquid cooling cabinets 101, a server 102 immersed in the cooling liquid of the liquid cooling cabinet 101, a dry cooler 103, a heat exchanger 104, a refrigeration device 105, a first regulating valve 106, a second regulating valve 107, a liquid pump 108, a liquid storage tank 109, a liquid collector 110, a liquid distributor 111, and a controller (not shown in the figure), as well as pipelines connecting various assemblies, a first temperature sensor (not shown in the figure) arranged at the liquid outlet of the liquid cooling cabinet, a second temperature sensor (not shown in the figure) arranged at the liquid inlet of the liquid cooling cabinet, and a third temperature sensor (not shown in the figure) arranged on the server 102.

In embodiments of the present application, the liquid outlet of each liquid cooling cabinet of the plurality of liquid cooling cabinets 101 is provided with a first temperature sensor, and the first temperature sensor is configured to detect the sub-liquid outlet temperature of the cooling liquid flowing out of each liquid cooling cabinet. The liquid inlet of each liquid cooling cabinet is provided with a second temperature sensor, and the second temperature sensor is configured to detect the sub-liquid inlet temperature of the cooling liquid flowing into each liquid cooling cabinet.

In embodiments of the present application, a surface of each server of the plurality of servers 102 is provided with a third temperature sensor, and the third temperature sensor is configured to detect a temperature of the server surface. In addition, a fourth temperature sensor configured to detect the ambient temperature of the environment where the liquid cooling system is located is also provided.

In embodiments of the present application, the liquid distributor 111 includes a plurality of branch pipes respectively connected to the liquid inlets of respective liquid cooling cabinets 101, and the liquid collector 110 includes a plurality of branch pipes respectively connected to the liquid outlets of respective liquid cooling cabinets 101, to have effect of buffering, stabilizing the flow, mixing and evenly distributing the fluid on the cooling liquid.

In embodiments of the present application, the liquid storage tank 109 is arranged between the liquid outlet end of the dry cooler 103 and the liquid inlet end of the liquid pump 108, so that not only can cavitation of the liquid pump 108 be prevented, but also the flow of the liquid cooling working medium may be adjusted in different refrigeration modes.

In embodiments of the present application, both the fan of the dry cooler 103 and the liquid pump 108 are variable frequency apparatuses, and the fan frequency or the liquid pump frequency may be adjusted according to the input control instruction, to increase or decrease the fan rotating speed or increase or decrease the rotating speed of the liquid pump.

In embodiments of the present application, the dry cooler 103, the first regulating valve 106, the second regulating valve 107 and the refrigerating device 105 may be automatically turned on or off according to the input control instruction. The refrigeration device 105 may be various refrigeration systems, such as chilled water system, air-cooled compressor refrigeration system, etc.

In embodiments of the present application, the liquid cooling system 100 is divided into two parts of independent pipelines, in which one part is a liquid cooling working medium circulation pipeline in communication with the liquid cooling cabinet 101, and the other part is an external independent refrigeration device circulation pipeline. The liquid cooling working medium circulation pipeline and the refrigeration device circulation pipeline exchange heat indirectly through the heat exchanger 104. Here, the liquid cooling working medium is also called cooling liquid.

In embodiments of the present application, the liquid cooling system 100 includes a natural refrigeration mode and an auxiliary refrigeration mode, and the switching between the natural refrigeration mode and the auxiliary refrigeration mode is controlled by opening and closing of the first regulating valve 106 and the second regulating valve 107. When the first regulating valve 106 is opened and the dry cooler 103 operates, and the second regulating valve 107 is closed and the refrigeration device 105 stops operation, the liquid cooling system is in the natural refrigeration mode. At this time, only the liquid cooling working medium circulation pipeline operates, and the heat generated by the liquid cooling cabinet 101 and the server 102 is taken away by the dry cooler 103. When the first regulating valve 106 is closed and the dry cooler 103 stops operation, and the second regulating valve 107 is opened and the refrigeration device 105 operates, the liquid cooling system is in the auxiliary refrigeration mode. At this time, both liquid cooling working medium circulation pipeline and the refrigeration device circulation pipeline operate, and the refrigeration device 105 is used to provide the refrigeration capacity required by the liquid cooling system, and the generated refrigeration capacity is transferred to the liquid cooling working medium through the heat exchanger 104.

Here, when the liquid cooling system is in the natural refrigeration mode, the circulation of the liquid cooling working medium is as follows: the liquid cooling working medium absorbs the heat of the server 102 in the liquid cooling cabinet 101, then flows out of the liquid cooling cabinet 101, and is collected in the liquid collector 110 through various branch pipes, and then converges and buffers in the liquid collector 110, and then flows into the dry cooler 103 from a main pipeline. At this time, the first regulating valve 106 is in an open state, and the temperature of the liquid cooling working medium is reduced under the cooling effect of the dry cooler 103. Subsequently, the liquid cooling working medium first passes through the liquid storage tank 109 and then enters the liquid pump 108, thus avoiding cavitation of the liquid pump. The liquid pump 108 provides power for the whole circulation, and the liquid cooling working medium enters the liquid distributor 111 under the action of the liquid pump 108, and in the liquid distributor 111 it is evenly distributed to various branch pipes and enters the liquid cooling cabinet 101 to start the next circulation. In the natural refrigeration mode, the liquid pump 108 and the fan of the dry cooler 103 can adjust the frequency or rotating speed according to the refrigeration demand of the liquid cooling cabinet, to match the corresponding refrigeration capacity.

Here, when the liquid cooling system is in the auxiliary refrigeration mode, the circulation of the liquid cooling working medium is as follows: the liquid cooling working medium absorbs the heat of the server 102 in the liquid cooling cabinet 101, then flows out of the liquid cooling cabinet 101, and is collected in the liquid collector 110 through various branch pipes, and then converges and buffers in the liquid collector 110, and then flows into the heat exchanger 104 from the main pipeline. At this time, the first regulating valve 106 is in the closed state and the liquid cooling working medium does not flow through the dry cooler 103, and the second regulating valve 107 is in the open state while the refrigeration device 105 is in the operation state. The two sets of pipelines exchange heat indirectly through the heat exchanger 104. After the liquid cooling working medium flows out of the heat exchanger 104, it enters the liquid pump 108 through the liquid storage tank 109. Under the action of the liquid pump 108, the liquid cooling working medium enters the liquid distributor 111, and in the liquid distributor it is evenly distributed to various branch pipes and enters the liquid cooling cabinet 101 to start the next circulation. In the auxiliary refrigeration mode, the frequency of the liquid pump 108 and the refrigeration capacity of the refrigeration device 105 may be adjusted according to the refrigeration demand of the liquid cooling cabinet, to match the corresponding refrigeration capacity.

It should be noted that the switching of the refrigeration modes of the liquid cooling system, the rotating speeds of the liquid pump 108 and the fan of the dry cooler 103, and the refrigeration capacity of the refrigeration device 105 are all adjusted by the controller. Here, the control flow of the controller is as follows.

At step 1, the controller obtains the ambient temperature T0, the sub-liquid inlet temperatures of the liquid cooling working medium at the liquid inlets of respective liquid cooling cabinets, such as Ta1, Ta2, Ta3 . . . , the sub-liquid outlet temperatures of the liquid cooling working medium at the liquid outlets of respective liquid cooling cabinets, such as Tc1, Tc2, Tc3 . . . , and the surface temperatures of respective servers, such as Tb1, Tb2, Tb3 . . . .

Here, the environment where the liquid cooling system is located, the liquid inlets of respective liquid cooling cabinets, the liquid outlets of respective liquid cooling cabinets and the surfaces of the server are taken as monitoring points, and the temperatures of respective monitoring point are collected by temperature sensors.

At step 2, the controller averages a plurality of sub-liquid inlet temperatures to obtain an average liquid inlet temperature Ta, averages a plurality of sub-liquid outlet temperatures to obtain an average liquid outlet temperature Tc, and obtains the highest surface temperature Tb from the surface temperatures of all servers.

Here, the controller collects and processes the temperatures of respective monitoring points, and finally obtains four temperature points, namely, the first is the ambient temperature T0; the second is the average liquid inlet temperature Ta obtained by averaging the liquid inlet temperatures Ta1, Ta2 and Ta3, etc.; the third is the average liquid outlet temperature Tc obtained by averaging the liquid outlet temperatures Tc1, Tc2 and Tc3, etc.; and the fourth is the highest surface temperature Tb obtained by taking the maximum from surface temperatures Tb1, Tb2 and Tb3, etc. of respective servers.

At step 3, based on the ambient temperature T0 and the average liquid outlet temperature Tc, the switching of refrigeration modes of the liquid cooling system is controlled.

Here, the ambient temperature T0 is compared with the average liquid outlet temperature Tc, and the liquid outlet temperature is generally 40-50° C., and the temperature difference ΔT (ΔT=Tc−T0) between the average liquid outlet temperature Tc and the ambient temperature T0 is obtained. When the temperature difference ΔT is less than a first temperature threshold C, such as 10° C., the liquid cooling system is controlled to switch to the auxiliary refrigeration mode. At this time, the first regulating valve 106 and the dry cooler 103 are closed, and the second regulating valve 107 and the refrigeration device are opened. When the temperature difference ΔT between the average liquid outlet temperature Tc and the ambient temperature T0 is greater than or equal to the first temperature threshold C, the liquid cooling system is controlled to switch to the natural refrigeration mode, the second regulating valve 107 and the refrigeration device 105 are closed, and the first regulating valve 106 and the dry cooler 103 are opened. In order to avoid frequent switching of refrigeration modes, a first duration threshold t1 is set, such as 30 minutes, that is, a first duration of the temperature difference ΔT less than the first temperature threshold C is greater than or equal to the first duration threshold t1, or the first duration of the temperature difference ΔT greater than or equal to the first temperature threshold C is greater than or equal to the first duration threshold t1, the refrigeration mode is switched.

At step 4, based on the average liquid inlet temperature Ta and the second temperature threshold value A, the fan frequency of the dry cooler 103 or the refrigeration capacity of the refrigeration device 105 is adjusted.

Here, the average liquid inlet temperature Ta is compared with the second temperature threshold A. For example, the second temperature threshold A is 45° C. When the average liquid inlet temperature Ta is greater than the second temperature threshold A, it indicates that the current temperature of the liquid cooling working medium is high, and it is necessary to strengthen the heat exchange with the outside. At this time, if the liquid cooling system is in the natural refrigeration mode, the fan frequency of the dry cooler 103 is increased, thereby increasing the rotating speed of the dry cooler 103 and accelerating the heat exchange speed. If the liquid cooling system is in the auxiliary refrigeration mode, the cooling capacity of the refrigeration device 105 is increased and the heat exchange speed is accelerated.

When the average liquid inlet temperature Ta is less than or equal to the second temperature threshold value A, it indicates that the current temperature of the liquid cooling working medium is low and there is no need to exchange excessive heat with the outside. At this time, if the liquid cooling system is in the natural refrigeration mode, the fan frequency of the dry cooler 103 is reduced, thereby reducing the rotating speed of the dry cooler 103 and slowing down the heat exchange speed. If the liquid cooling system is in the auxiliary refrigeration mode, the cooling capacity of the refrigeration device 105 is reduced and the heat exchange speed is slowed down.

In order to avoid frequent adjustment of the dry cooler or refrigeration device, a second duration threshold t2 is set, such as 15 minutes, that is, when the average liquid inlet temperature Ta is less than or equal to the second temperature threshold A for 15 minutes, or the average liquid inlet temperature Ta is greater than the second temperature threshold A for 15 minutes, the fan frequency of the dry cooler 103 or the refrigeration capacity of the refrigeration device 105 is adjusted.

At step 5, based on the highest surface temperature Tb and the third temperature threshold B, the liquid pump frequency of the liquid pump is adjusted.

Here, the highest surface temperature Tb is compared with the third temperature threshold B, for example, the third temperature threshold B is 70° C. When the highest surface temperature Tb is greater than the third temperature threshold B, it indicates that the current surface temperature of at least one server is high, and the refrigeration capacity needs to be increased. At this time, the frequency of the liquid pump 108 is increased, to increase the rotating speed of the liquid pump 108, accelerate the circulation speed of the liquid cooling working medium and improve the refrigeration capacity. When the highest surface temperature Tb is less than or equal to the third temperature threshold B, it indicates that the current surface temperatures of all servers are relatively normal. At this time, the frequency of the liquid pump 108 is reduced to save power consumption.

In order to avoid frequent adjustment of the liquid pump, a third duration threshold B is set, such as 10 minutes, that is, when the highest server surface temperature Tb is less than or equal to the third temperature threshold B for 10 minutes, or the highest server surface temperature Tb is greater than the third temperature threshold B for 10 minutes, the liquid pump frequency of the liquid pump 108 is adjusted.

As may be seen from the above, in embodiments of the present application, the temperature points of different monitoring points are used as the control basis to automatically adjust the operation of each component of the control system to match the corresponding refrigeration capacity. Temperature sensors are provided at multiple points to understand the operation of the system, and the control of devices is associated with different temperature points, to realize all-round control of the whole system. At the same time, on the basis of making full use of natural cold source, devices such as liquid storage tank, liquid distributor and liquid collector are set up to ensure the stability of flow in the system and the safety of all components of the system. Furthermore, auxiliary refrigeration related apparatus and pipelines are provided to ensure uninterrupted refrigeration of the system and maintain the reliable operation of the server under extreme weather conditions.

It should be noted that in embodiments of the present application, at least one step may be selected to execute among the third step, the fourth step and the fifth step, and there is no sequential order among the third step, the fourth step and the fifth step.

It should be understood that references to “an embodiment” or “one embodiment” or “an embodiment of the present application” or “the aforementioned embodiments” or “some embodiments” or “some implementations” throughout the specification mean that specific features, structures or characteristics related to the embodiments are included in at least one embodiment of the present application. Therefore, the appearances of “in an embodiment” or “in one embodiment” or “the embodiment of the present application” or “the aforementioned embodiment” or “some embodiments” or “some implementations” in various places throughout the specification do not necessarily refer to the same embodiment. Furthermore, these specific features, structures or characteristics may be combined in any suitable manner in one or more embodiments. It should be understood that in various embodiments of the present application, the serial number of the above-mentioned processes does not mean the order of execution, and the order of execution of each process should be determined according to its function and internal logic, and should not constitute any limitation on the implementation process of the embodiments of the present application. The above serial numbers of the embodiments of the present application are only for description, and do not represent the advantages and disadvantages of the embodiments.

In several embodiments provided by the present application, it should be understood that the disclosed devices and methods may be realized in other ways. The embodiments of device described above are only schematic. For example, the division of units is only a logical function division. In actual implementation, there may be other division methods, such as: multiple units or components may be combined or integrated into another system, or some features may be ignored or not implemented. In addition, the mutual coupling, direct coupling or communication connection of various components shown or discussed may be through some interfaces, indirect coupling or communication connection of devices or units, and may be electrical, mechanical or other forms.

The units described above as separate components may or may not be physically separated, and the components shown as units may or may not be physical units. It may be located in one place or distributed to multiple network units. Some or all of the units may be selected according to actual needs to achieve the purpose of the embodiment.

In addition, all the functional units in each embodiment of the present application may be integrated into one processing unit, or each unit may be implemented as a unit separately, or two or more units may be integrated into one unit. The above integrated units may be realized in the form of hardware, or in the form of hardware plus software functional units.

Those skilled in the art can understand that all or part of the steps to realize the above-mentioned method embodiment may be completed by hardware related to program instructions, and the above-mentioned program may be stored in a computer-readable storage medium, which, when executed, executes the steps including the above-mentioned method embodiment. The aforementioned storage media include various media that can store program codes, such as mobile storage devices, Read Only Memory (ROM), magnetic disks or optical disks.

Alternatively, if the integrated units mentioned above in the present application are realized in the form of software functional modules and sold or used as independent products, they can also be stored in a computer-readable storage medium. Based on such understanding, the essence or rather the part that contributes to the related art of the technical scheme of the embodiment of the present application may be embodied in the form of a software product, which is stored in a storage medium and includes several instructions to make a computer device (which may be a personal computer, a server, a network device, etc.) execute all or part of the methods of various embodiments of the present application. The aforementioned storage media include: mobile storage devices, ROM, magnetic disks or optical disks and other media that can store program codes.

It is worth noting that the drawings in the embodiment of the present application are only for explaining the schematic positions of various devices on the terminal apparatus, and do not represent the real positions in the terminal apparatus. The real positions of various devices or areas may be changed or shifted according to the actual situation (for example, the structure of the terminal apparatus), and the proportions of different parts in the terminal apparatus in the drawings do not represent the real proportions.

The above is only the implementation of the present application, to which the protection scope of the present application is not limited. Any person familiar with this technical field can easily think of changes or substitutions within the technical scope disclosed in the present application, which should be included in the protection scope of the present application. Therefore, the protection scope of the present application should be based on the protection scope of the claims.

### INDUSTRIAL PRACTICABILITY

The present application provides a liquid cooling system, which relates to the field of heat exchange of servers. The liquid cooling system includes a liquid cooling cabinet, a server immersed in the cooling liquid of the liquid cooling cabinet, a dry cooler, a heat exchanger, a refrigeration device and a controller. The liquid cooling cabinet is connected to the dry cooler to form a natural cold source refrigeration circulation branch. The liquid cooling cabinet is connected to the hot side of the heat exchanger to form a first circulation branch, the cold side of the heat exchanger is connected to the refrigeration device to form a second circulation branch, and an auxiliary refrigeration circulation branch includes the first circulation branch and the second circulation branch. The heat exchanger is connected in parallel with the dry cooler in parallel. The controller is configured to control opening or closing of the communication of the refrigeration circulation branches to enter different refrigeration modes, and the refrigeration circulation branches include the natural cold source refrigeration circulation branch and the auxiliary refrigeration circulation branch. That is, the liquid cooling system provided by the present application only reuses the parts of the liquid cooling cabinet and the server for the natural cold source refrigeration circulation branch and the auxiliary refrigeration circulation branch, and selects to open or close the communication of different refrigeration circulation branches, to enter different refrigeration modes to cool the cooling liquid, and then uses the cooled cooling liquid to continuously absorb the heat generated by the liquid cooling cabinet and the server. In this way, it not only solves the problem of poor cooling effect when only natural cold source is used for refrigeration, but also avoids the continuous operation of the compressor, saving power resources and energy, ensuring the reliability of the system, and maintaining the reliable operation of the server.

1. A liquid cooling system, comprising:
a liquid cooling cabinet,
a server immersed in a cooling liquid of the liquid cooling cabinet,
a dry cooler,
a heat exchanger,
a refrigeration device, and
a controller;
wherein the liquid cooling cabinet is connected to the dry cooler to form a natural cold source refrigeration circulation branch;
the liquid cooling cabinet is connected to a hot side of the heat exchanger to form a first circulation branch, and a cold side of the heat exchanger is connected to the refrigeration device to form a second circulation branch; the auxiliary refrigeration circulation branch comprises the first circulation branch and the second circulation branch, and the heat exchanger is connected in parallel with the dry cooler; and
the controller is configured to control opening or closing of the communication of refrigeration circulation branches to enter different refrigeration modes, and the refrigeration circulation branches comprise the natural cold source refrigeration circulation branch and the auxiliary refrigeration circulation branch.

2. The system according to claim 1, further comprising: a first regulating valve arranged in the natural cold source refrigeration circulation branch,
wherein the controller is further configured to obtain a first instruction to enter a natural refrigeration mode, and in response to the first instruction, control the first regulating valve to open the communication of the natural cold source refrigeration circulation branch and control the dry cooler to operate.

3. The system according to claim 2, further comprising: a first temperature sensor arranged at a liquid outlet of the liquid cooling cabinet, wherein the first temperature sensor is configured to detect a liquid outlet temperature of the cooling liquid flowing out of the liquid cooling cabinet; and
the controller is further configured to obtain an ambient temperature and obtain a first difference of the liquid outlet temperature minus the ambient temperature, and generate the first instruction when the first difference is greater than or equal to a first temperature threshold.

4. The system according to claim 1, further comprising a second regulating valve arranged in the first circulation branch,
wherein the controller is further configured to obtain a second instruction to enter an auxiliary refrigeration mode, and in response to the second instruction, control the second regulating valve to open the communication of the auxiliary refrigeration circulation branch and control the refrigeration device to operate.

5. The system according to claim 4, further comprising: a first temperature sensor arranged at a liquid outlet of the liquid cooling cabinet, wherein the first temperature sensor is configured to detect a liquid outlet temperature of the cooling liquid flowing out of the liquid cooling cabinet; and
the controller is further configured to obtain an ambient temperature and obtain a first difference of the liquid outlet temperature minus the ambient temperature, and generate the second instruction when the first difference is less than a first temperature threshold.

6. The system according to claim 2, wherein,
the controller is further configured to obtain a third instruction to switch from the natural refrigeration mode to an auxiliary refrigeration mode, and in response to the third instruction, control the first regulating valve to close the communication of the natural cold source refrigeration circulation branch, control the dry cooler to stop operation, control the second regulating valve to open the communication of the first circulation branch, and control the refrigeration device to operate.

7. The system according to claim 6, wherein,
the controller is further configured to obtain an ambient temperature, obtain a first difference of a liquid outlet temperature of the cooling liquid flowing out of the liquid cooling cabinet minus the ambient temperature, obtain a first duration of the first difference greater than or equal to a first temperature threshold when the first difference is greater than or equal to the first temperature threshold, and generate the third instruction when the first duration is greater than or equal to a first duration threshold.

8. The system according to claim 2, wherein,
the controller is further configured to obtain a fourth instruction to switch from an auxiliary refrigeration mode to the natural refrigeration mode, and in response to the fourth instruction, control the first regulating valve to open the communication of the natural cold source refrigeration circulation branch, control the dry cooler to operate, control the second regulating valve to close the communication of the first circulation branch, and control the refrigeration device to stop operation.

9. The system according to claim 8, wherein,
the controller is further configured to obtain an ambient temperature, obtain a first difference of a liquid outlet temperature of the cooling liquid flowing out of the liquid cooling cabinet minus the ambient temperature, obtain a first duration of the first difference less than a first temperature threshold when the first difference is less than the first temperature threshold, and generate the fourth instruction when the first duration is greater than or equal to a first duration threshold.

10. The system according to claim 2, further comprising a plurality of liquid cooling cabinets and a first temperature sensor arranged at a liquid outlet of each liquid cooling cabinet, wherein each first temperature sensor is configured to detect a sub-liquid outlet temperature of the cooling liquid flowing out of each liquid cooling cabinet; and
the controller is further configured to determine an average value of all sub-liquid outlet temperatures as a liquid outlet temperature.

11. The system according to claim 1, wherein,
the controller is further configured to obtain a parameter raising instruction for controlling a fan frequency of the dry cooler or a refrigeration capacity of the refrigeration device, and in response to the parameter raising instruction, raise the fan frequency of the dry cooler or increase the refrigeration capacity of the refrigeration device.

12. The system according to claim 11, further comprising: a second temperature sensor arranged at a liquid inlet of the liquid cooling cabinet, wherein the second temperature sensor is configured to detect a liquid inlet temperature of the cooling liquid flowing into the liquid cooling cabinet; and
the controller is further configured to obtain a second duration of the liquid inlet temperature greater than a second temperature threshold when the liquid inlet temperature is greater than the second temperature threshold, and generate the parameter raising instruction when the second duration is greater than or equal to a second duration threshold.

13. The system according to claim 1, wherein,
the controller is further configured to obtain a parameter reduction instruction for controlling a fan frequency of the dry cooler or a refrigeration capacity of the refrigeration device, and in response to the parameter reduction instruction, reduce the fan frequency of the dry cooler or the refrigeration capacity of the refrigeration device.

14. The system according to claim 13, further comprising: a second temperature sensor arranged at a liquid inlet of the liquid cooling cabinet, wherein the second temperature sensor is configured to detect a liquid inlet temperature of the cooling liquid flowing into the liquid cooling cabinet; and
the controller is further configured to obtain a second duration of the liquid inlet temperature less than or equal to a second temperature threshold when the liquid inlet temperature is less than or equal to the second temperature threshold, and generate the parameter reduction instruction when the second duration is greater than or equal to a second duration threshold.

15. The system according to claim 11, further comprising a plurality of liquid cooling cabinets and a second temperature sensor arranged at a liquid inlet of each liquid cooling cabinet, wherein each second temperature sensor is configured to detect a sub-liquid inlet temperature of the cooling liquid flowing into each liquid cooling cabinet; and
the controller is further configured to determine an average value of all sub-liquid inlet temperatures as a liquid inlet temperature.

16. The system according to claim 1, further comprising a liquid pump arranged between the liquid cooling cabinet and the dry cooler or between the liquid cooling cabinet and the hot side of the heat exchanger;
wherein the controller is further configured to obtain a frequency raising instruction for controlling a liquid pump frequency of the liquid pump, and in response to the frequency raising instruction, raise the liquid pump frequency of the liquid pump.

17. The system of claim 16, further comprising: a third temperature sensor arranged on the server, wherein the third temperature sensor is configured to detect a surface temperature of the server; and
the controller is further configured to obtain a third duration of the surface temperature greater than a third temperature threshold when the surface temperature is greater than the third temperature threshold, and generate the frequency raising instruction when the third duration is greater than or equal to a third duration threshold.

18. The system according to claim 1, further comprising a liquid pump arranged between the liquid cooling cabinet and the dry cooler or between the liquid cooling cabinet and the hot side of the heat exchanger;
wherein the controller is further configured to obtain a frequency reduction instruction for controlling a liquid pump frequency of the liquid pump, and in response to the frequency reduction instruction, reduce the liquid pump frequency of the liquid pump.

19. The system of claim 18, further comprising: a third temperature sensor arranged on the server, wherein the third temperature sensor is configured to detect a surface temperature of the server; and
the controller is further configured to obtain a third duration of the surface temperature less than or equal to a third temperature threshold when the surface temperature is less than or equal to the third temperature threshold, and generate the frequency reduction instruction when the third duration is greater than or equal to a third duration threshold.

20. The system according to claim 16, further comprising a liquid storage tank, where the liquid pump is arranged between the liquid cooling cabinet and the dry cooler, and the liquid storage tank is arranged between the liquid pump and the dry cooler; or the liquid pump is arranged between the liquid cooling cabinet and the hot side of the heat exchanger, and the liquid storage tank is arranged between the liquid pump and the hot side of the heat exchanger.

21. (canceled)

22. (canceled)
